(19) United States
(12) Patent Application Publication
(10) Pub. No.: US 2014/0340177 A1
(43) Pub. Date: Nov. 20, 2014

(54) RESONANT CIRCUIT, DISTRIBUTED AMPLIFIER, AND OSCILLATOR

(71) Applicant: Kenichi Hosoya, Tokyo (JP)

(72) Inventor: Kenichi Hosoya, Tokyo (JP)

(73) Assignee: NEC CORPORATION, Minato-ku, Tokyo (JP)

(21) Appl. No.: 14/364,378

(22) PCT Filed: Dec. 6, 2012
(86) PCT No.: PCT/JP2012/082268

§ 371 Date: Jun. 11, 2014

(30) Foreign Application Priority Data
Dec. 14, 2011 (JP) 2011-273121

(51) Int. Cl. H01P 7/00; H03F 1/56; H03B 5/12; H03H 9/46; H03F 3/193

(52) U.S. Cl. CPC H03H 9/46; H03F 1/56; H03F 3/193; H03B 5/1206; H03F 2200/255
USPC 333/219; 330/302

(57) ABSTRACT

In order to provide a resonant circuit in which the variation in the coupling coefficient with the process fluctuation of the capacitance value is suppressed in a resonant circuit composed of a transmission line and a capacitance, a resonant circuit according to an exemplary aspect of the invention includes a stub; a first capacitance whose one to be connected to the stub and whose another end to be grounded; and a second capacitance whose one end to be connected to a connection between the stub and the first capacitance.

### TECHNICAL FIELD

The present invention relates to a resonant circuit, a distributed amplifier, and an oscillator.

### BACKGROUND ART

A cascode distributed amplifier is used for various use applications including a data signal amplifier such as a modulator driver in an optical communication system and a wide band amplifier and the like in a radio communication system.

FIG. 12 illustrates an example of a circuit configuration of a cascode distributed amplifier. The cascode distributed amplifier includes a plurality of sections 21-k (k=1 to n). Here, n is an integer representing the number of stages (the number of sections). Each section 21-k is configured to mainly include a transistor and a transmission line or a distributed constant line. Each section 21-k is connected in a distributed manner. The cascode distributed amplifier includes, as external terminals, an input terminal 22 through which a high speed signal or a high-frequency signal is input, an output terminal 23 through which an amplified high speed signal or an amplified high-frequency signal is output, a collector power supply terminal 24, a base power supply terminal 25, and a cascode power supply terminal 26. For example, an HBT (Heterojunction Bipolar Transistor) is used as a transistor.

Next, the configuration of each section 21-k will be described. An HBT 27-k (k=1 to n) and a cascode HBT 28-k (k=1 to n) are connected in a cascade configuration and form a cascode pair HBT 32-k (k=1 to n). A transmission line 29-k (k=1 to n) can be inserted between the collector terminal of HBT 27-k and the emitter terminal of the cascode HBT 28-k. The emitter terminal of the HBT 27-k is grounded. The base terminal of the cascode HBT 28-k is grounded for a high-frequency (alternate-current) through a cascode grounded capacitor 30-k (k=1 to n). For a DC (direct current), a cascode voltage is supplied from the cascode power supply terminal 26 through a cascode power-supply resistance 31-k (k=1 to n). The base terminal of the HBT 27-k is connected to input-side high impedance lines 34-k and 35-k (k=1 to n) through a transmission line 33-k (k=1 to n). The base voltage is supplied from the base power supply terminal 25 to the base terminals of these HBT 27-k through a base power-supply resistance 40. Similarly, the collector terminal of the cascode HBT 28-k is connected to output-side high impedance lines 37-k and 38-k (k=1 to n) through a transmission line 36-k (k=1 to n). The collector voltage is supplied from the collector power supply terminal 24 to the collector terminal of these cascode HBT 28-k through a collector power-source resistance 39.

In an amplifier with such configuration, the parasitic reactance components of the HBT 27-k and the cascode HBT 28-k are coupled with the high impedance transmission lines 34-k, 35-k, and 37-k, 38-k. As a result, it is known that, in such amplifier, a pseudo transmission line having a high cutoff frequency and characteristic impedance close to signal-source impedance and load impedance is formed, and amplifying characteristics having an almost constant gain over a wide band can be realized.

Although the above-mentioned cascode distributed amplifier has wide-band and high-gain characteristics, an output reflection loss increases in a high frequency band outside but just near the required band, which leads to occurrence of a negative resistance in some cases. This makes the stability of a circuit deteriorate and unstable operations such as parasitic oscillation occur.

It is necessary, therefore, to suppress the output reflection loss which has deteriorated in high frequency band, and necessary to avoid the deterioration of gain characteristics in such case. As mentioned above, the deterioration of such output reflection loss, however, mostly arises just near the required band. It is generally difficult, therefore, to suppress the output reflection loss without deterioration of gain characteristics.

As solutions to such problem, patent literature 1, 2, and 3 disclose a technology as shown in FIG. 13 and FIG. 14. In this technology, a reflection loss suppression circuit 51 is connected to an output end 50 of a distributed amplifier. FIG. 14 illustrates a detailed configuration of a resonant circuit 80 used in the reflection loss suppression circuit 51. In this technology, the configuration of a part other than the reflection loss suppression circuit 51 is the same as that of the distributed amplifier shown in FIG. 12, and an identical symbol is attached to an identical part. In the description of this technology, an example calculation for a three-stage cascode distributed amplifier (n=3 in FIG. 13) is used.

In order to describe circuit operations, an output reflection coefficient Γₒᵤₜᵢ (i=1, 2, 3) and an output impedance Zₒᵤₜᵢ (i=1, 2, 3) are defined in FIG. 13. FIG. 15 is a Smith chart on which output reflection coefficients Γₒᵤₜᵢ (i=1, 2, 3) in a frequency band in which the reflection loss should be suppressed are plotted. In this example, a case is used where the absolute value of Γₒᵤₜ₁ exceeds one, that is to say, the negative resistance arises in the distributed amplifier itself. The following description is also true for a case where the absolute value of Γₒᵤₜ₁ does not exceed one, that is to say, the negative differential resistance does not arise in the distributed amplifier itself.

The reflection loss suppression circuit 51 of this technology includes a transmission line 52 connected to the output end 50 of the distributed amplifier in series, and a resistance grounded circuit 53 which is connected to the transmission line 52 in parallel as viewed from the side of the output terminal 23 and has frequency selectivity. The resistance grounded circuit 53 is composed of a resistance 54 and the resonant circuit 80 whose detailed configuration is shown in FIG. 14.

The resonant circuit 80 is composed of a capacitance 82 and a (λ/2−δ)-length open stub 81 whose length is shorter than the half wavelength of a fundamental wave by δ at a resonant frequency. Here, δ is assumed to be sufficiently shorter than the wavelength λ of the fundamental wave. The capacitance value C of the capacitance 82 is selected so that formula (1) may be satisfied at the fundamental wave angular frequency ω₀.

$$Im [ tan h \{ γ ( \frac{λ}{2} - δ ) \} ] = - {ω}_{0} {CZ}_{0 r} \qquad ( 1 )$$

Here, Z₀ᵣ and γ represent a characteristic impedance at the fundamental wave frequency of the (λ/2−δ)-length open stub 81 and a propagation constant. It is described in patent literature 1, 2, and 3 that such configuration enables the resonant circuit 80 to exhibit series resonance characteristics having strong frequency selectivity.

Next, operations of the reflection loss suppression circuit 51 including the resonant circuit 80 will be described using FIG. 13 and FIG. 15. The output reflection coefficient Γₒᵤₜ₁ in the case where the increase in a reflection loss in the target band to be suppressed (near 78 to 82 GHz in this case) causes a negative resistance to arise, is moved to near infinite distance point on a Smith chart by means of the transmission line 52. That is to say, the output impedance Zₒᵤₜ₁ is converted into the high impedance Zₒᵤₜ₂. Next, the reflection coefficient Γₒᵤₜ₂ is converted into Γₒᵤₜ₃ by connecting the resistance grounded circuit 53 in parallel. Here, by setting the resistance value of the resistance 54 to a numerical value around the load impedance, Γₒᵤₜ₃ reaches near the center of the Smith chart. That is to say, the high impedance Zₒᵤₜ₂ is converted into the impedance Zₒᵤₜ₃ near to the load impedance. The output reflection loss in the target band to be suppressed, therefore, is suppressed. On the other hand, because of the strong frequency selectivity which the resistance grounded circuit 53 has, the effects on circuit characteristics outside the target band to be suppressed are suppressed small. In this example, it can be avoided that the frequency characteristics of the gain deteriorate greatly due to including the reflection loss suppression circuit 51.

In FIG. 16, the frequency dependence of an output reflection loss is illustrated in a case without the reflection loss suppression circuit 51 (corresponding to FIG. 12) and a case with the reflection loss suppression circuit 51 (corresponding to FIG. 13). It is found that the output reflection loss near the target band to be suppressed (near 78 to 82 GHz) is sufficiently suppressed. On the other hand, FIG. 17 illustrates the frequency dependence of the gain at that time. It is found that the deterioration of gain characteristics due to including the reflection loss suppression circuit 51 is very small.

As mentioned above, by adding the reflection loss suppression circuit 51 which is mainly configured by a resonant circuit with strong frequency selectivity composed of a capacitance and a transmission line, it is possible to reduce the deterioration of the output reflection loss in the high frequency area, which is peculiar to the cascode distributed amplifier, without sacrificing gain characteristics.

In the above description, an example has been described in which a resonant circuit with strong frequency selectivity composed of a capacitance and a transmission line is applied to the cascode distributed amplifier. An example of the application of such resonant circuit, however, is not limited to this.

FIG. 18 illustrates an example in which the resonant circuit 80 composed of a capacitance and a transmission line is applied to a millimeter-wave band oscillator with a fixed frequency.

This millimeter-wave band oscillator includes an output terminal 61, a base power supply terminal 62, and a collector power supply terminal 63. An HBT 64 is used as an oscillation active element. The emitter terminal of the HBT is grounded through a transmission line 65. A base power supply circuit 69 is connected to the base terminal of the HBT 64 through a transmission line 66. The base power supply circuit 69 is composed of a quarter-wavelength transmission line 71 and a grounded capacitance 73. The base power supply terminal 62 is connected to the connection point of the quarter-wavelength transmission line 71 and the grounded capacitance 73, and the base power source is supplied from the terminal. Similarly, the collector power supply circuit 70 is connected to the collector terminal of the HBT 64 through a transmission line 67. The collector power supply circuit 70 is composed of a quarter-wavelength transmission line 72 and a grounded capacitance 74. The collector power supply terminal 63 is connected to the connection point of the quarter-wavelength transmission line 72 and the grounded capacitance 74, and the collector power source is supplied from the terminal. An output matching circuit 75 is connected to the connection point of the transmission line 67 and the collector power supply circuit 70. The output matching circuit 75 is composed of a transmission line 68 and an open stub 76. The oscillation output is output from the output terminal 61 to the outside through the output matching circuit 75 and a DC blocking capacitance 77. On the other hand, the resonant circuit 80 is connected to the connection point of the transmission line 66 and the base power supply circuit 69. The resonant circuit 80 is the same as that described in the example of the application of the above-mentioned cascode distributed amplifier, and is composed of the (λ/2−δ)-length open stub 81 and the capacitance 82.

Generally, it is possible to realize an oscillator with low phase noise and high frequency stability by means of using a resonant circuit having such strong frequency selectivity.
Patent Literature 1: Japanese Patent No. 3865043
Patent Literature 2: U.S. Pat. No. 7,129,804
Patent Literature 3: U.S. Pat. No. 7,173,502

### DISCLOSURE OF INVENTION

### Problem to be Solved by the Invention

In such resonant circuit as that shown in FIG. 14, however, a coupling coefficient varies greatly when a capacitance value of the capacitance 82 fluctuates. The graph shown in FIG. 19 represents calculated results of a change in a coupling coefficient obtained by circuit simulation on the assumption that a capacitance value of the capacitance 82 fluctuates within the range of ±20%. In a semiconductor integrated circuit technology, in order to realize a resonant circuit as shown in FIG. 14, a MIM (Metal Insulator Metal) capacitance is usually employed as the capacitance 82. Here, a film thickness and a film quality of a dielectric film used for the MIM capacitance have the potential to vary within a wafer, among wafers, and among lots. Moreover, considering a reduction in the frequency of trial production in the developmental process or the like, a design error of a MIM capacitance value should also be taken into consideration. Accordingly, a capacitance value fluctuation comparable to that shown in FIG. 19 has to be assumed.

The fluctuation of a coupling coefficient of a resonant circuit as shown in FIG. 19 greatly changes the amount suppressed of the output reflection loss in the cascode distributed amplifier shown in FIG. 13. Here, a calculation example of a four-stage cascode distributed amplifier is described. FIG. 20 is a diagram in which the results of circuit simulation of the output reflection loss (absolute value of S₂₂) and the gain (absolute value of S₂₁) are plotted for the cases where a capacitance value of the capacitance 82 in the reflection loss suppression circuit 51 is equal to a design value (solid line), fluctuates by −20% (dashed line), and by +20% (dotted line). Concerning the output reflection loss, it is also illustrated with a chain line for the case without the reflection loss suppression circuit 51 (corresponding to FIG. 12).

As shown in FIG. 20, the amount suppressed of the output reflection loss (absolute values of S₂₂) in the target band to be suppressed (65 to 85 GHz in this example) fluctuates greatly with the capacitance value of the capacitance 82 varying.

In the above description, the effects of the fluctuation in the coupling coefficient of a resonant circuit due to variations of the capacitance value on the amount suppressed of the output reflection loss in the cascode distributed amplifier have been described. However, an example in which the fluctuation in the coupling coefficient of a resonant circuit has a crucial influence on circuit characteristics is not limited to this.

Generally, the coupling coefficient of a resonant circuit has a powerful effect on the output level of an oscillator. FIG. 21 illustrates the dependence of the oscillation output of a millimeter-wave band (43 GHz band) oscillator shown in FIG. 18 on the capacitance value of the capacitance 82. The denoted values are simulation results by means of a harmonic balance method. Thus, the output level of an oscillator fluctuates greatly with the fluctuation in the coupling coefficient of the resonant circuit 80 which varies depending on the capacitance value of the capacitance 82.

The present invention has been made in view of the problems mentioned above, and the objective of the present invention is to provide a resonant circuit in which the variation in the coupling coefficient with the process fluctuation of the capacitance value is suppressed in a resonant circuit composed of a transmission line and a capacitance.

### Means for Solving a Problem

A resonant circuit according to an exemplary aspect of the invention includes a stub; a first capacitance whose one to be connected to the stub and whose another end to be grounded; and a second capacitance whose one end to be connected to a connection between the stub and the first capacitance.

### Effect of the Invention

According to a resonant circuit, a distributed amplifier, and an oscillator of the present invention, it is possible to suppress the variation in a coupling coefficient with the process fluctuation of a capacitance value in a resonant circuit including a transmission line and a capacitance.

### BRIEF DESCRIPTION OF THE DRAWINGS

FIG. 1 is a diagram illustrating an example of a circuit configuration of a resonant circuit in accordance with the first exemplary embodiment.

FIGS. 2A, 2B, and 2C are Smith charts to illustrate operations of a circuit in accordance with the first exemplary embodiment.

FIG. 3 is a graph illustrating the simulation results of a coupling coefficient of a circuit in accordance with the first exemplary embodiment.

FIG. 4 is a diagram illustrating an example of a circuit configuration of a resonant circuit in accordance with the second exemplary embodiment.

FIG. 5 is a diagram illustrating an example of a circuit configuration of a resonant circuit in accordance with the third exemplary embodiment.

FIG. 6 is a diagram illustrating an example of a circuit configuration of a resonant circuit in accordance with the fourth exemplary embodiment.

FIG. 7 is a graph illustrating the simulation results of a gain and an output reflection loss of a circuit in accordance with the fourth exemplary embodiment.

FIG. 8 is a diagram illustrating an example of a circuit configuration of a resonant circuit in accordance with the fifth exemplary embodiment.

FIG. 9 is a diagram illustrating an example of a circuit configuration of a resonant circuit in accordance with the sixth exemplary embodiment.

FIG. 10 is a graph illustrating the simulation results of oscillation output of a circuit in accordance with the sixth exemplary embodiment.

FIG. 11 is a graph illustrating the simulation results of an oscillation frequency of a circuit in accordance with the sixth exemplary embodiment.

FIG. 12 is a diagram illustrating an example of a circuit configuration of a cascode distributed amplifier.

FIG. 13 is a diagram illustrating an example of a circuit configuration of a cascode distributed amplifier.

FIG. 14 is a diagram illustrating an example of a circuit configuration of a resonant circuit.

FIG. 15 is a Smith chart to illustrate operations of a reflection loss suppression circuit.

FIG. 16 is a graph to illustrate operations of a reflection loss suppression circuit.

FIG. 17 is a graph to illustrate operations of a reflection loss suppression circuit.

FIG. 18 is a diagram illustrating an example of a circuit configuration of an oscillator.

FIG. 19 is a graph illustrating a capacitance value fluctuation in a coupling coefficient of a resonant circuit.

FIG. 20 is a graph illustrating a capacitance value fluctuation in an output reflection loss of a distributed amplifier.

FIG. 21 is a graph illustrating a capacitance value fluctuation in an output level of an oscillator.

### DESCRIPTION OF EMBODIMENTS

Hereinafter, although the present invention will be described by an exemplary embodiment of the invention, the following exemplary embodiments do not limit the invention in accordance with the claims, and it is not necessary to use all of combinations of the features described in the exemplary embodiments as the means for solving a problem of the invention.

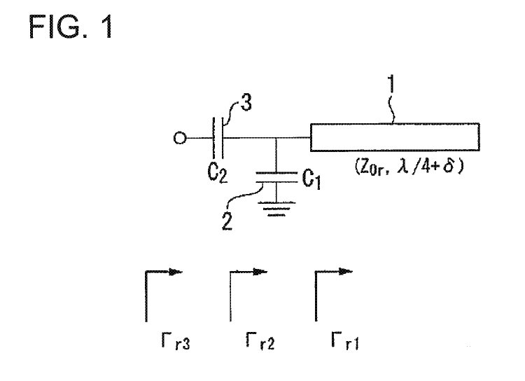

FIG. 1 illustrates an example of a circuit configuration of a resonant circuit in accordance with the first exemplary embodiment. The resonant circuit of the first exemplary embodiment includes a (λ/4+δ)-length open stub 1, a grounded capacitance 2, and a capacitance 3.

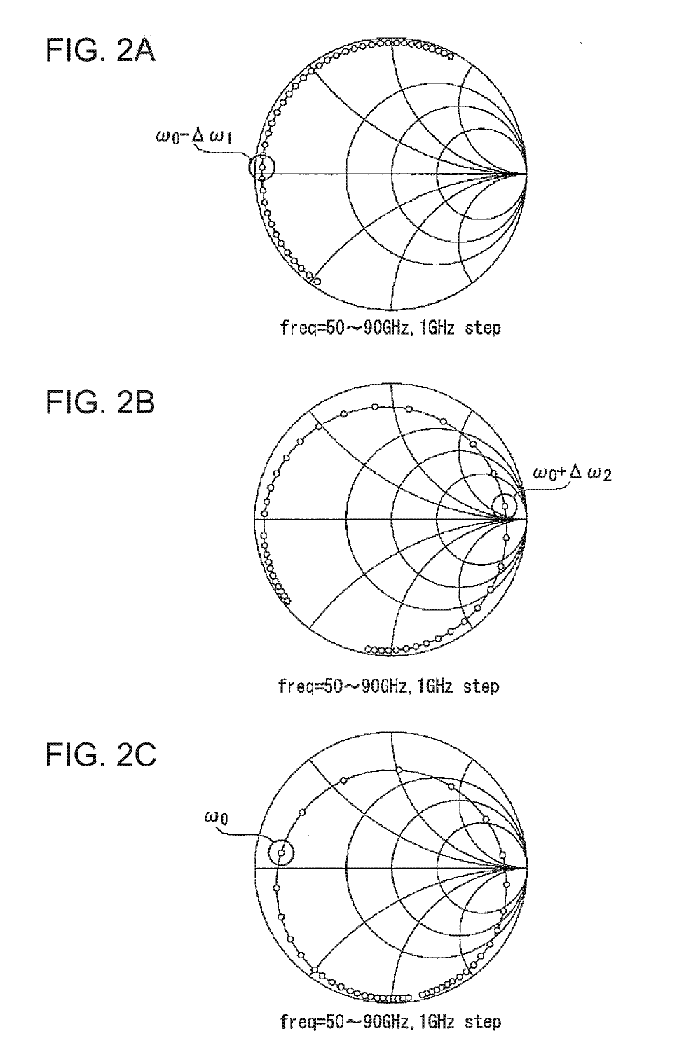

The (λ/4+δ)-length open stub 1 has a length longer than the quarter-wavelength of the fundamental wave by δ in the fundamental resonance frequency (angular frequency ω₀). Here, δ is assumed to be sufficiently shorter than the wavelength λ of the fundamental wave. By the (λ/4+δ)-length open stub 1 by itself, therefore, a series resonance circuit is formed at a frequency slightly lower than the fundamental resonance frequency (angular frequency ω₀−Δω₁). FIG. 2A illustrates the reflection coefficient Γᵣ₁ which is defined in FIG. 1. The capacitance value of the grounded capacitance 2 is set to a value by which a circuit composed of the (λ/4+δ)-length open stub 1 and the grounded capacitance 2 forms a parallel resonance circuit at a frequency slightly higher than the fundamental resonance frequency (the angular frequency ω₀+Δω₂). FIG. 2B illustrates the reflection coefficient Γᵣ₂ which is defined in FIG. 1. The capacitance value of the capacitance 3 is set to a value by which the resonant circuit as a whole including the capacitance 3 forms a series resonance circuit at the fundamental resonance frequency (the angular frequency ω₀). FIG. 2C illustrates the reflection coefficient Γᵣ₃ which is defined in FIG. 1.

In the following description, it will be analytically described that the coupling coefficient of the resonant circuit of the first exemplary embodiment does not depend on a capacitance value fluctuation. It is possible to calculate the coupling coefficient β_{C} of the resonant circuit of the first exemplary embodiment on the basis of formulae (2) and (3) under the approximation that the (λ/4+δ)-length open stub 1 is a low-loss device.

$$\begin{matrix}{β}_{C} = \frac{{Z}_{0}}{{R}_{S}} & ( 2 ) \\ {R}_{S} ≅ {Z}_{0 r} \frac{\frac{α l}{{cos}^{2} ( β l )}}{{\{ \frac{α l}{{cos}^{2} ( β l )} \}}^{2} + {\{ ω {C}_{2} {Z}_{0 r} + tan ( β l ) \}}^{2}} & ( 3 )\end{matrix}$$

Here, R_{S} represents a series resistance component of a series resonance circuit. Z₀ᵣ represents a characteristic impedance of the (λ/4+δ)-length open stub 1. α represents an attenuation constant of the (λ/4+δ)-length open stub 1. β represents a phase constant of the (λ/4+δ)-length open stub 1. 1 represents a length of the (λ/4+δ)-length open stub 1, and 1=λ/4+6. And Z₀ represents a constant such as a characteristic impedance of a transmission line to which the resonant circuit is connected or a system impedance. Here, formula (3) is changed into formula (4) if a resonance condition under the no-loss approximation is applied.

$${R}_{S} ≅ {Z}_{0 r} \frac{α l [ 1 + {\{ {ω}_{0} ( {C}_{1} + {C}_{2} ) {Z}_{0 r} \}}^{2} ]}{{{( α l )}^{2} [ 1 + {\{ {ω}_{0} ( {C}_{1} + {C}_{2} ) {Z}_{0 r} \}}^{2} ]}^{2} + {( {ω}_{0} {C}_{1} {Z}_{0 r} )}^{2}} \qquad ( 4 )$$

Here, if a term including the square of a loss (α1)² in the denominator is ignored and approximate expression (5) is applied in the numerator, formula (4) is approximated by formula (6).

$$\begin{matrix}{\{ {ω}_{0} ( {C}_{1} + {C}_{2} ) {Z}_{0 r} \}}^{2} >> 1 & ( 5 ) \\ {R}_{S} ≅ {Z}_{0 r} α {l ( 1 + \frac{{C}_{2}}{{C}_{1}} )}^{2} & ( 6 )\end{matrix}$$

Generally, it can be considered that MIM capacitance values formed closely on an identical semiconductor chip indicate a similar tendency of variation. Since only ratio of capacitance values (C₂/C₁) is included in formula (6), it is predicted that the coupling coefficient of the resonant circuit of the present exemplary embodiment does not depend on a capacitance value fluctuation.

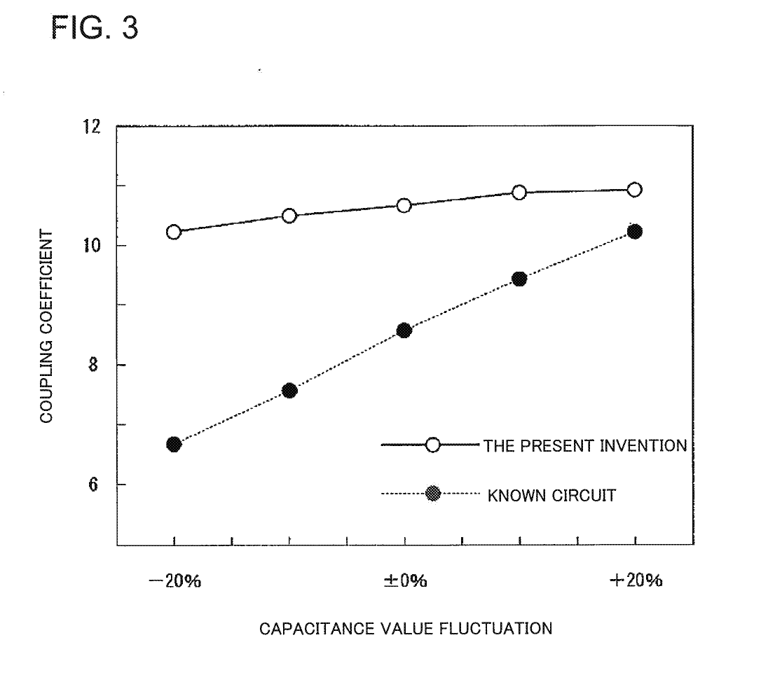

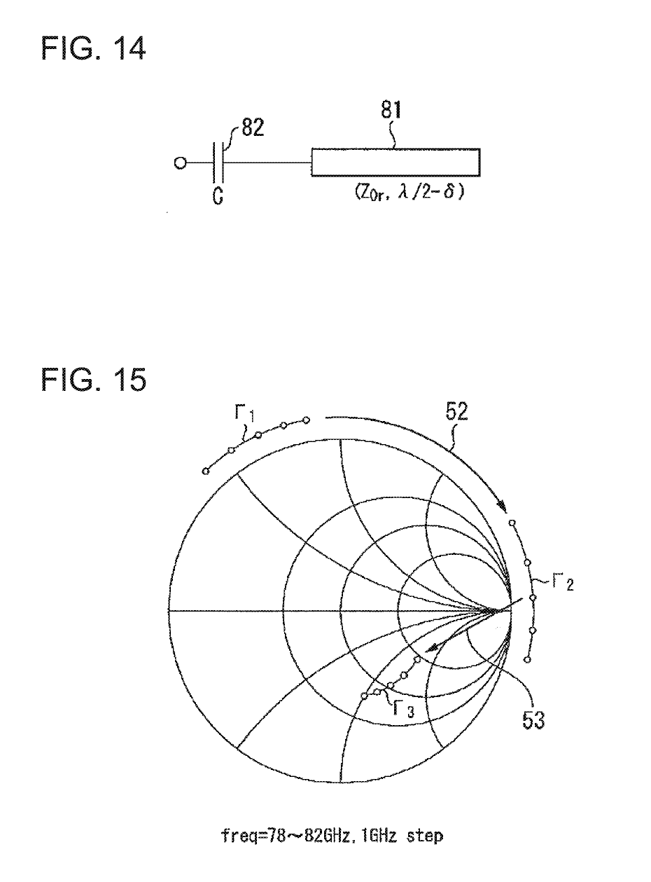

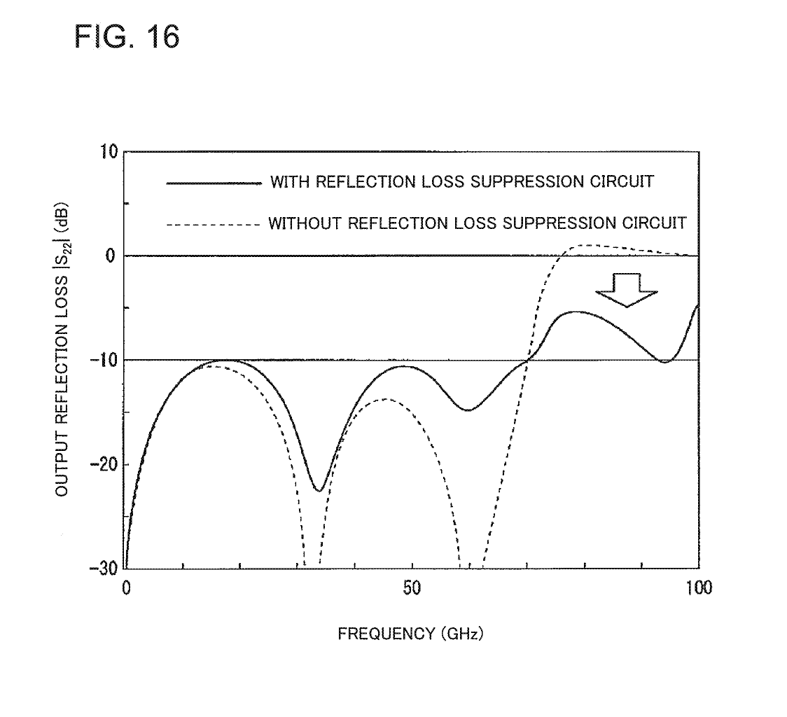

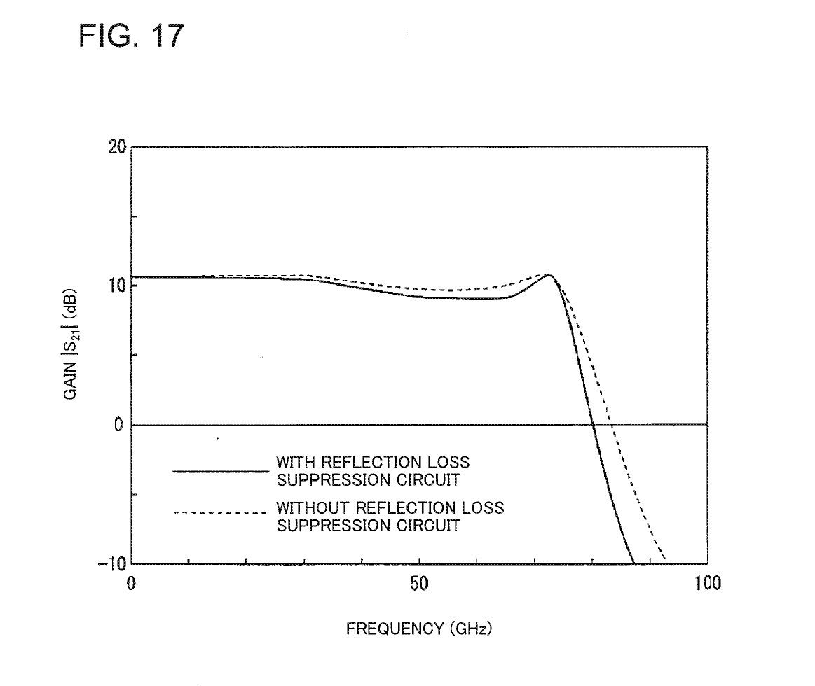

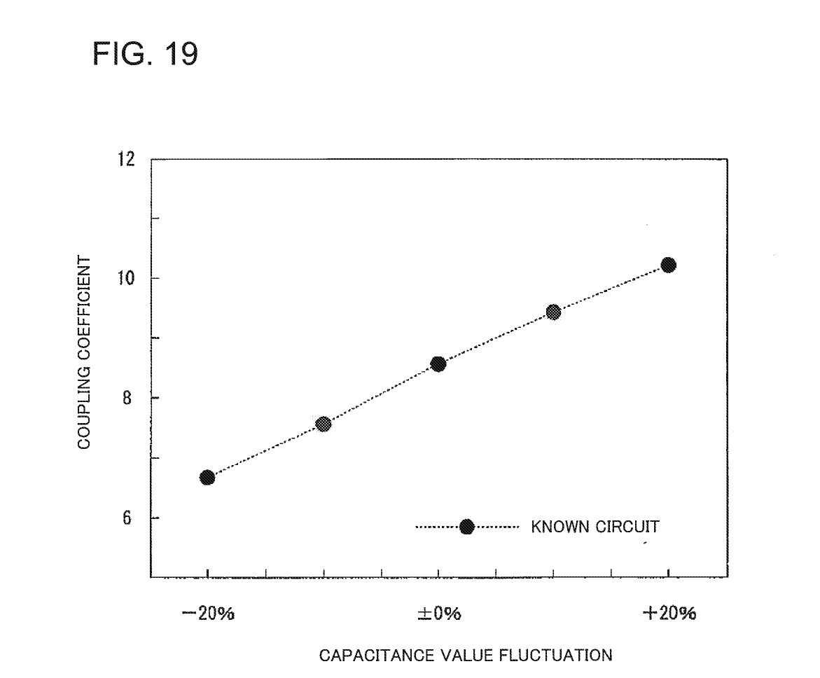

Next, the above-mentioned analytical prediction will be confirmed by means of numerical calculation (circuit simulation). Open circles and a solid line in FIG. 3 represents the results of calculation of the variation in a coupling coefficient by means of circuit simulation on the assumption that the grounded capacitance 2 and the capacitance 3 fluctuate simultaneously within the range of ±20% by the same rate in the resonant circuit of the present exemplary embodiment shown in FIG. 1. For comparison, the variation in the coupling coefficient on the assumption that the capacitance value of the capacitance 82 fluctuates in the resonant circuit shown in FIG. 14 is represented by filled circles and a dashed line (the same as that in FIG. 19). As shown in this figure, the capacitance value variation in the coupling coefficient of the resonant circuit of the present exemplary embodiment is suppressed more greatly than the capacitance value variation in the resonant circuit shown in FIG. 14. This result is consistent with the above-mentioned analytical prediction.

Although MIM capacitance has been used as an example of the grounded capacitance 2 and the capacitance 3, other kinds of capacitances are also available as long as they indicate a similar tendency of variation in a case where they are formed closely on an identical semiconductor chip. In addition, the (λ/4+δ)-length open stub 1 can be realized by a microstrip line (MSL), a coplanar waveguide (CPW) or the like.

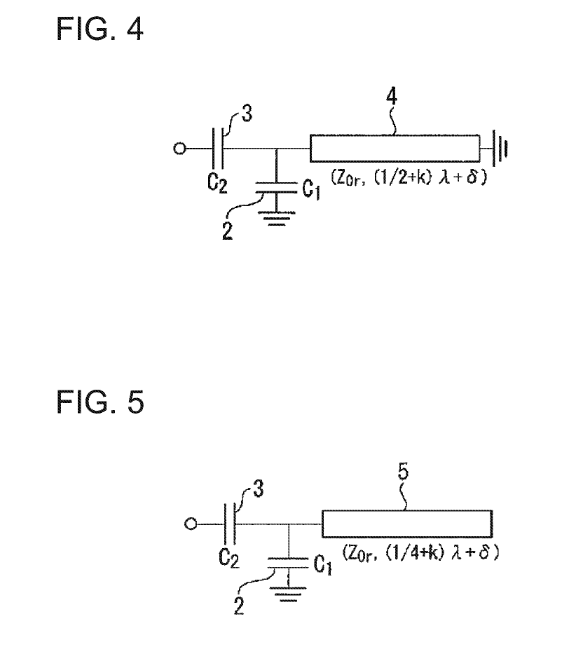

The second exemplary embodiment will be described using a circuit diagram shown in FIG. 4. An identical symbol is attached to a component which functions just like that in FIG. 1. For this reason, the detailed description about such component will be omitted.

In the present exemplary embodiment, the (λ/4+δ)-length open stub 1 in the first exemplary embodiment shown in FIG. 1 is replaced with a ((½+k)λ+δ)-length short stub 4. The ((½+k)λ+δ)-length short stub 4 is assumed to have a length longer than the (½+k) wavelength of the fundamental wave by δ in the fundamental resonance frequency. Here, δ is sufficiently shorter than the wavelength λ of the fundamental wave, and k is a non-negative integer.

The operation mechanism is the same as that of the first exemplary embodiment. By adopting such a configuration as that of the present exemplary embodiment, it becomes possible to obtain stronger frequency selectivity than that in the first exemplary embodiment. However, there is a disadvantage that the chip area increases. In addition, since a pole is formed below the fundamental resonance frequency, it is unsuitable for the application to a wideband circuit such as a distributed amplifier.

The third exemplary embodiment will be described using a circuit diagram shown in FIG. 5. An identical symbol is attached to a component which functions just like that in FIG. 1. For this reason, the detailed description about such component will be omitted.

In the present exemplary embodiment, the (λ/4+δ)-length open stub 1 in the first exemplary embodiment shown in FIG. 1 is replaced with a ((¼+k)λ+δ)-length open stub 5. The ((¼+k)λ+δ)-length open stub 5 is assumed to have a length longer than the (¼+k) wavelength of the fundamental wave by δ in the fundamental resonance frequency. Here, δ is sufficiently shorter than the wavelength λ of the fundamental wave, and k is a positive integer.

The operation mechanism is the same as that of the first exemplary embodiment. By adopting such a configuration as that of the present exemplary embodiment, it becomes possible to obtain stronger frequency selectivity than that in the first exemplary embodiment. However, there is a disadvantage that the chip area increases. In addition, since a pole is formed below the fundamental resonance frequency, it is not unsuitable for the application to a wideband circuit such as a distributed amplifier.

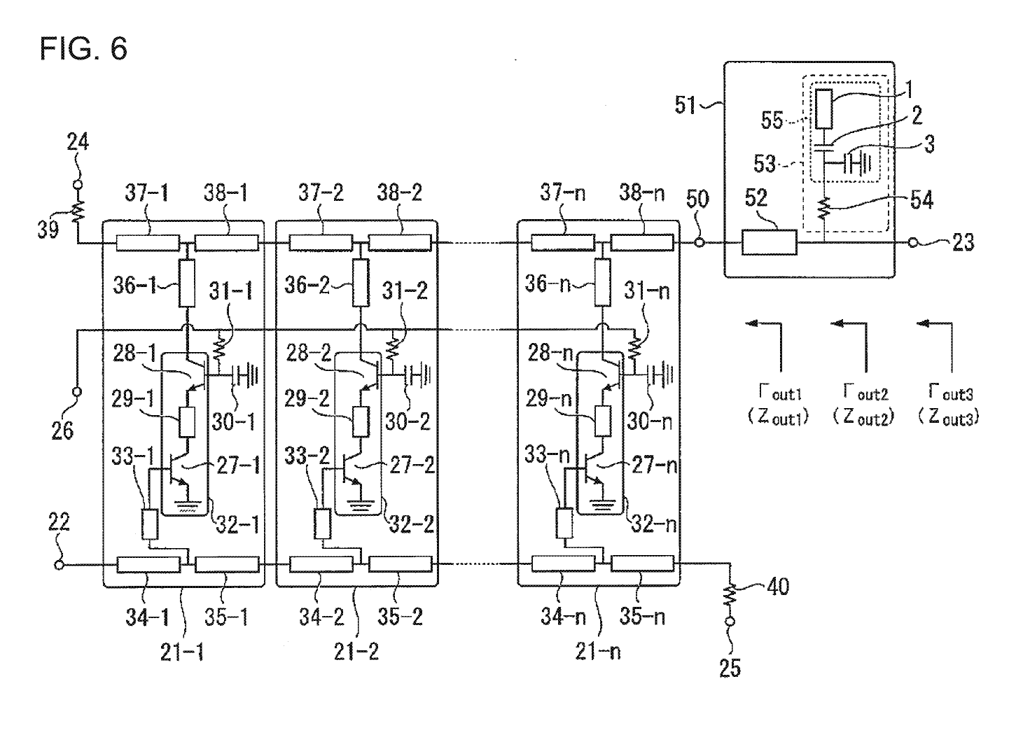

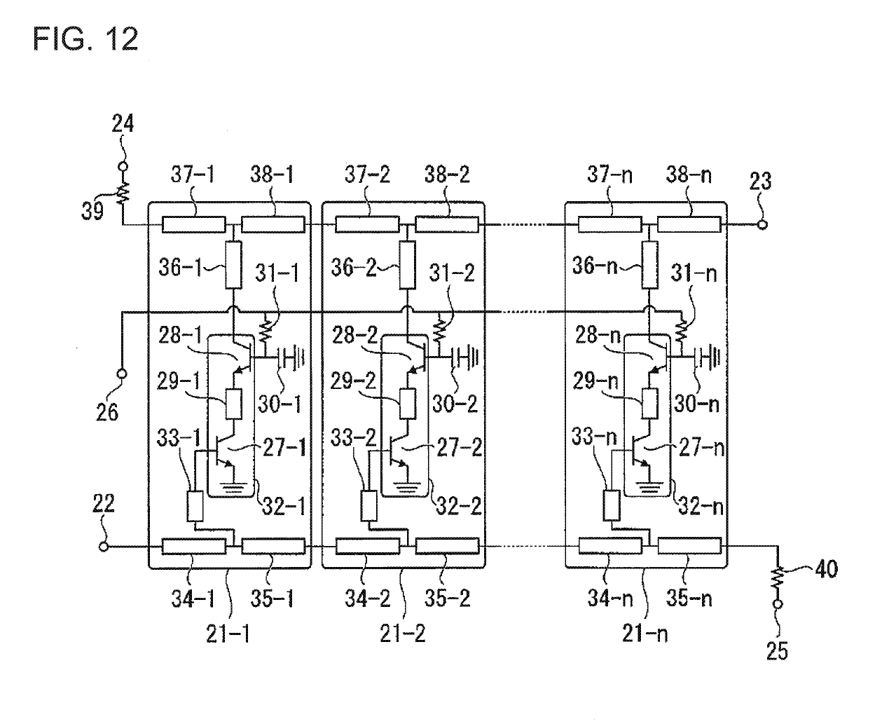

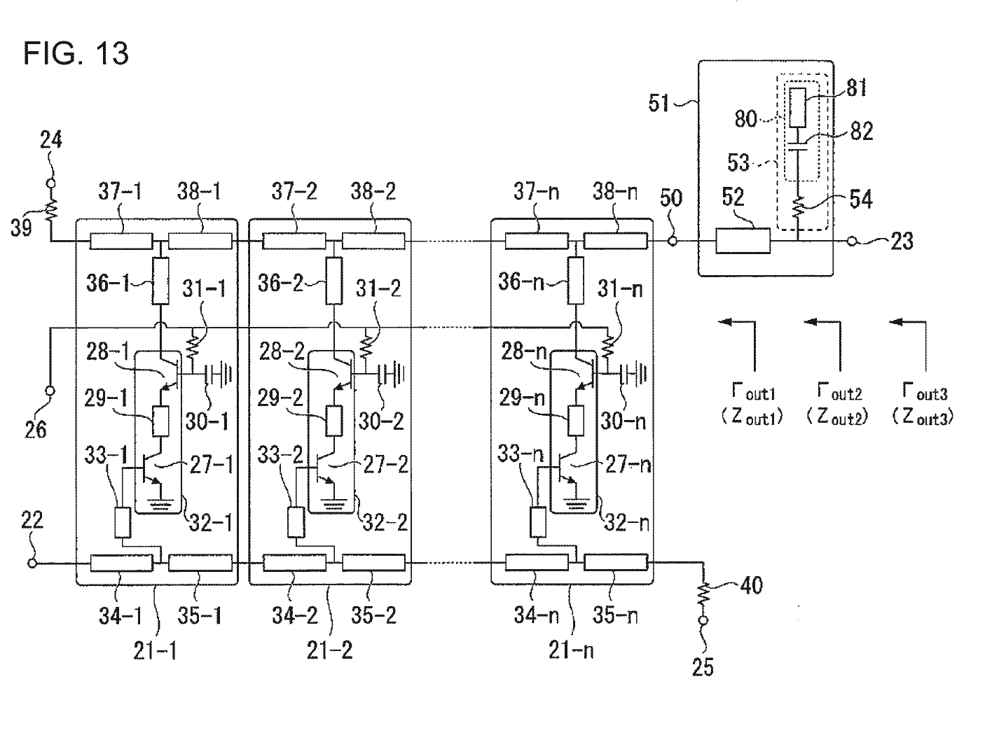

The fourth exemplary embodiment will be described using a circuit diagram shown in FIG. 6. An identical symbol is attached to a component which functions just like that in FIG. 1, FIG. 12, and FIG. 13. For this reason, the detailed description about such component will be omitted.

The present exemplary embodiment is an example in which the resonant circuit in the first exemplary embodiment shown in FIG. 1 is applied to a cascode distributed amplifier shown in FIG. 12. Concretely, the resonant circuit 80 in the reflection loss suppression circuit 51 which is added to the cascode distributed amplifier shown in FIG. 13 is replaced with the resonant circuit 55 in the first exemplary embodiment shown in FIG. 1.

The operation of the reflection loss suppression circuit 51 is the same as that described in Background Art using FIG. 13. That is to say, by adding the reflection loss suppression circuit 51, it becomes possible to suppress the output reflection loss in high-frequency area with minimal impact on gain characteristics.

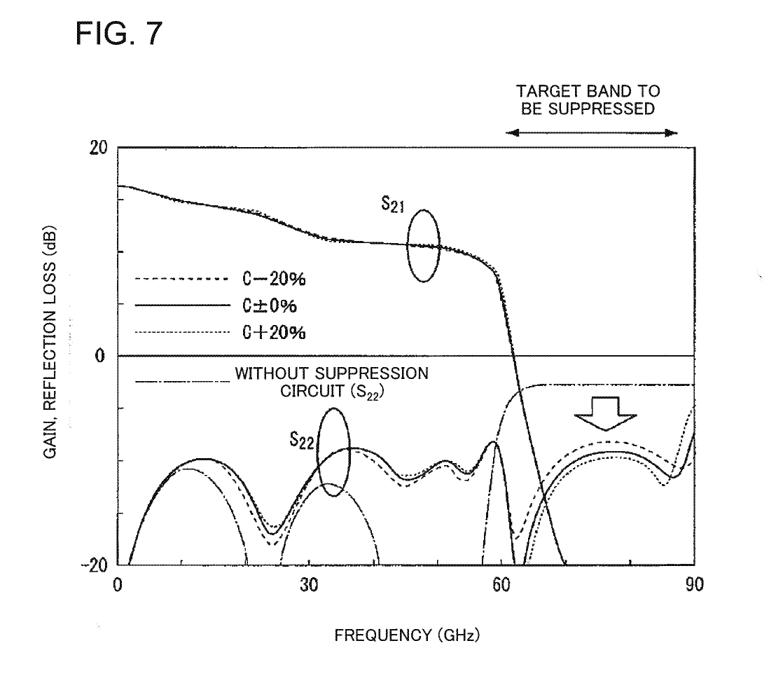

However, the stability of the amount suppressed of the output reflection loss to the capacitance value fluctuation in the resonant circuit is different. FIG. 7 is a diagram in which the results of circuit simulation of the output reflection loss (absolute values of S₂₂) and the gain (absolute values of S₂₁) are plotted for the cases where capacitance values of the grounded capacitance 2 and the capacitance 3 in the reflection loss suppression circuit 51 are equal to design values (solid line), fluctuate by −20% (dashed line), and by +20% (dotted line), respectively. Concerning the output reflection loss, it is also illustrated with a chain line for the case without the reflection loss suppression circuit 51 (corresponding to FIG. 12).

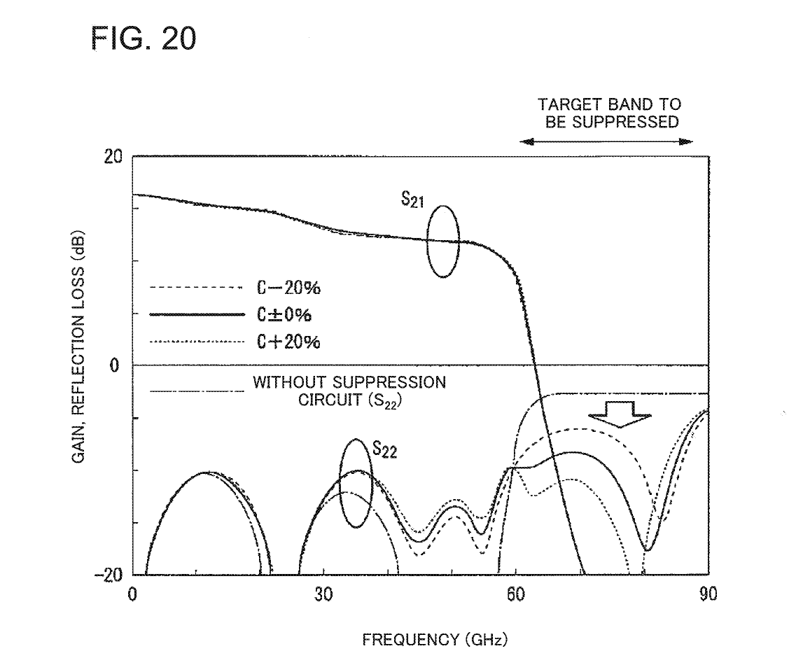

As shown in this figure, it is found that the amount suppressed of the output reflection loss (absolute values of S₂₂) in the target band to be suppressed (65 to 85 GHz in this example) does not depend largely on the capacitance value fluctuation of the grounded capacitance 2 and the capacitance 3, and the suppression of the output reflection loss has been stably achieved. The difference is obvious from the comparison to the case with the technology shown in FIG. 20.

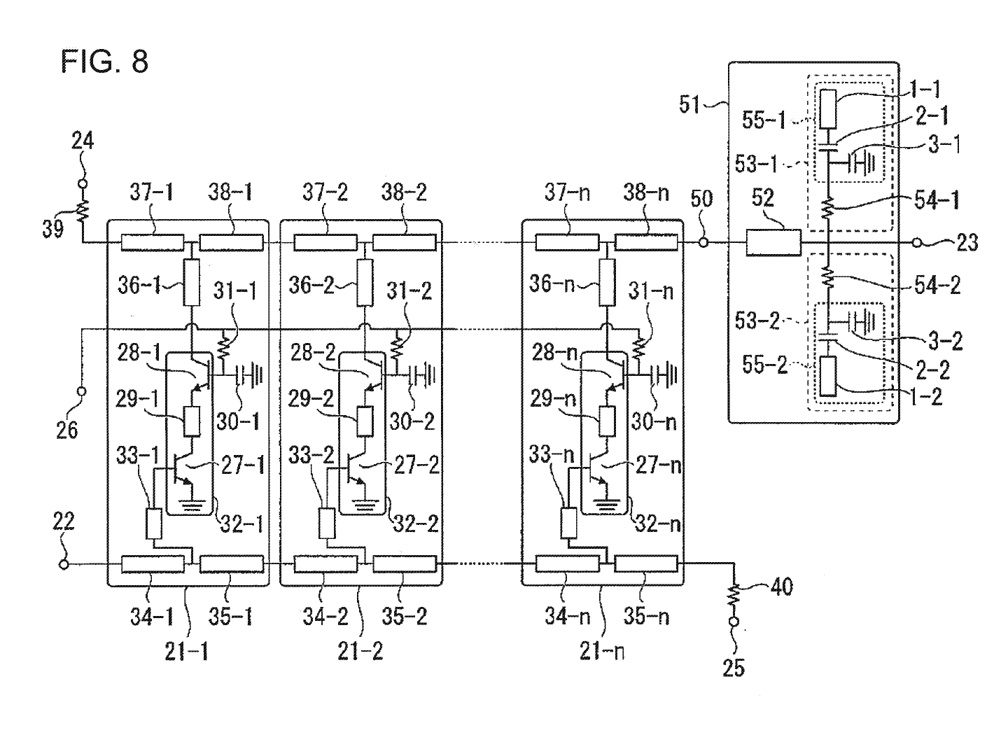

The fifth exemplary embodiment will be described using a circuit diagram shown in FIG. 8. An identical symbol is attached to a component which functions just like that in FIG. 1, FIG. 6, FIG. 12, and FIG. 13. For this reason, the detailed description about such component will be omitted.

In the fourth exemplary embodiment, the reflection loss suppression circuit 51 is composed of a single resonant circuit 55. It is also acceptable, however, for the reflection loss suppression circuit 51 to be configured using a plurality of resonant circuits each of which has a different resonance frequency. Adopting such a configuration promises the effect that the target band to be suppressed of the output reflection loss broadens.

In the example shown in FIG. 8, the reflection loss suppression circuit 51 is configured by connecting two resistance grounded circuits (53-1 and 53-2) to each other in parallel including resonant circuits 55-1 and 55-2 whose resonance frequencies differ from each other. In order to make resonance frequencies of the resonant circuits 55-1 and 55-2 different values, at least one of the lengths of (λ/4+δ)-length open stubs 1-1 and 1-2, the capacitance values of grounded capacitances 2-1 and 2-2, and the capacitance values of capacitances 3-1 and 3-2 can be made different values.

In the example shown in FIG. 8, the resonant circuits 55-1 and 55-2 are configured to be provided with the resistances 54-1 and 54-2, respectively. It is also acceptable, however, to be configured to connect a plurality of resonant circuits to a single resistance in which the resistances 54-1 and 54-2 are shared.

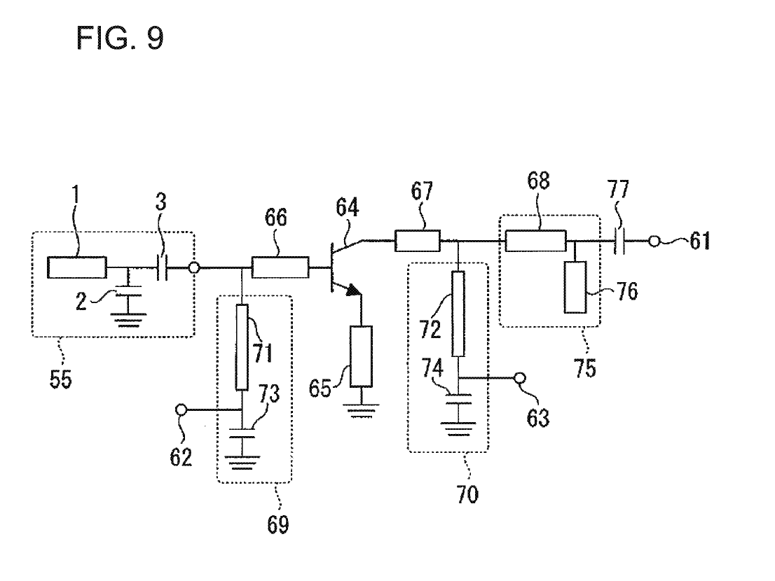

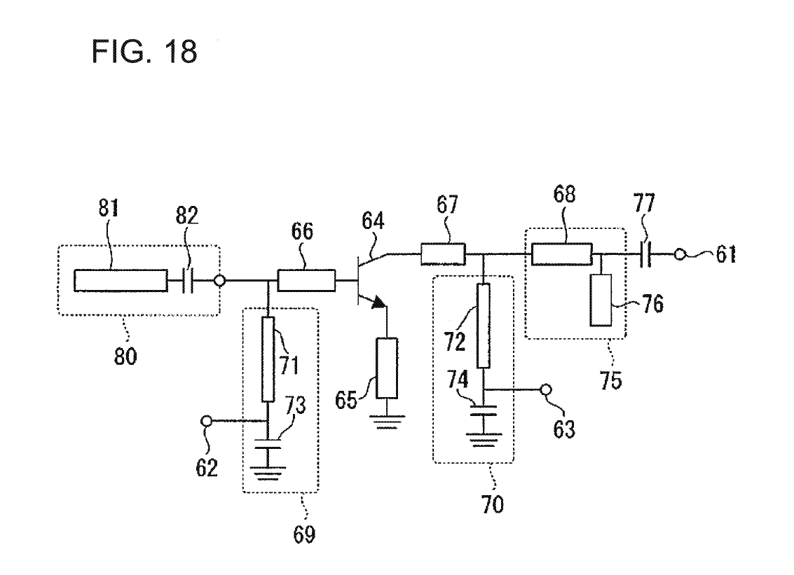

The sixth exemplary embodiment will be described using a circuit diagram shown in FIG. 9. An identical symbol is attached to a component which functions just like that in FIG. 18. For this reason, the detailed description about such component will be omitted.

The present exemplary embodiment is an example in which the resonant circuit in the first exemplary embodiment shown in FIG. 1 is applied to a millimeter-wave band (43 GHz band) oscillator with a fixed frequency.

In the millimeter-wave band oscillator of the present exemplary embodiment, a resonant circuit 55 instead of the resonant circuit 80 in FIG. 18 is connected to the connection point of the transmission line 66 and the base power supply circuit 69. The resonant circuit 55 is the same as that described in the first exemplary embodiment and is composed of the (λ/4+δ)-length open stub 1, the grounded capacitance 2, and the capacitance 3.

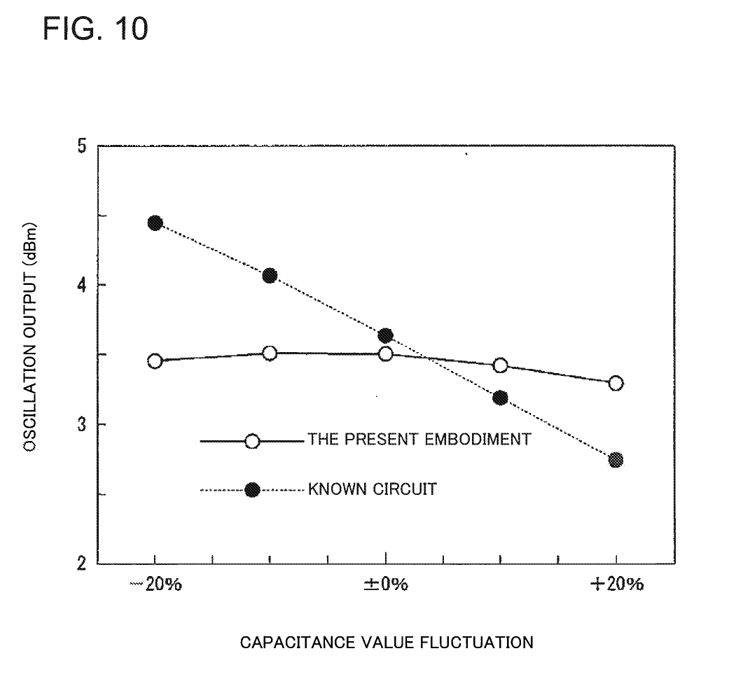

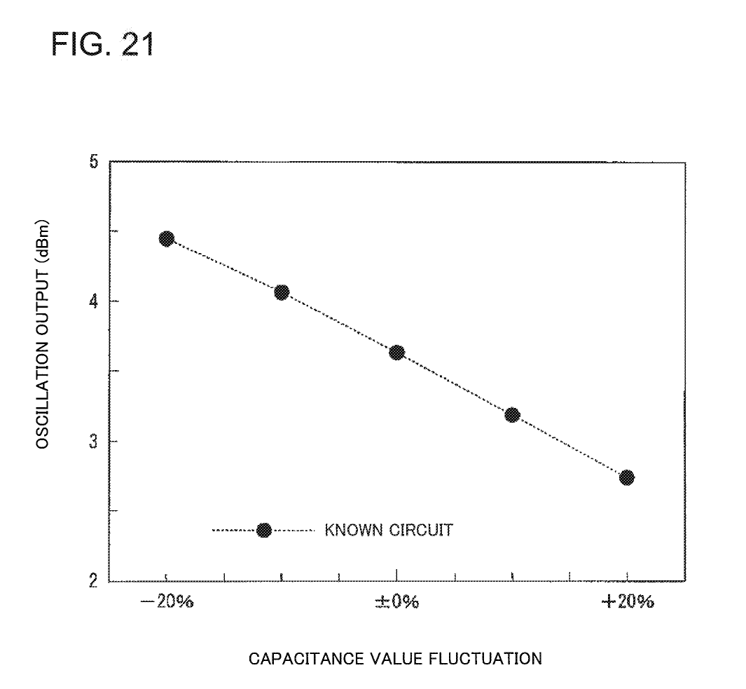

In the millimeter-wave band oscillator of the present exemplary embodiment, the variation in the oscillation output is represented by open circles and a solid line shown in FIG. 10 on the assumption that capacitance values of the grounded capacitance 2 and the capacitance 3 fluctuate simultaneously by the same rate. The denoted values are simulation results by means of a harmonic balance method. For comparison, the dependence of the oscillation output of the millimeter-wave band oscillator shown in FIG. 18 on the capacitance value of the capacitance 82 is represented by filled circles and a dashed line in this figure (the same as those shown in FIG. 21). As shown in the figure, the oscillator in the present exemplary embodiment has the effect that the variation in the oscillation output to the capacitance value fluctuation in the resonant circuit is greatly suppressed.

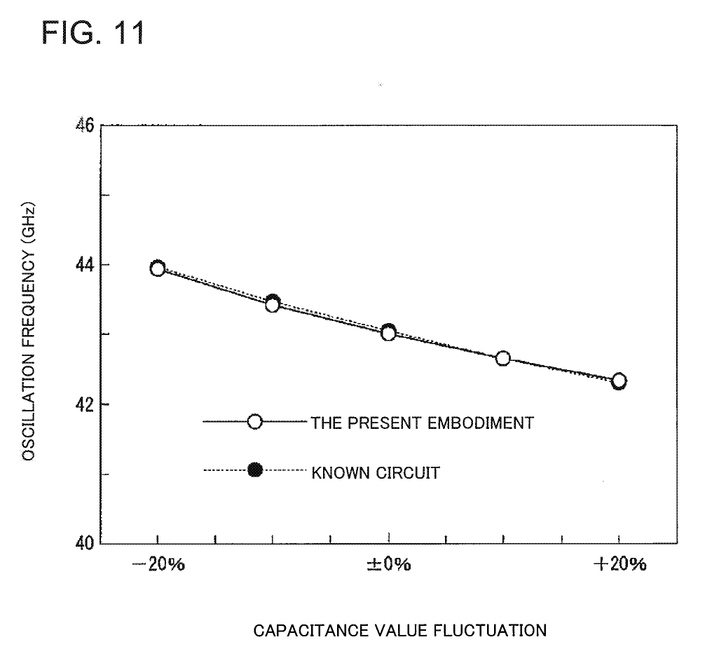

FIG. 11 illustrates the dependence of the oscillation frequency on the capacitance value. Thus, concerning the dependence of the oscillation frequency on the capacitance value, there is no significant difference between the circuit in the present exemplary embodiment and a known circuit.

In the fourth, fifth, and sixth exemplary embodiments, an HBT has been employed as an active element. It is also acceptable, however, to use a Si bipolar transistor and a field effect transistor (FET), as a matter of course. It is possible to use as an FET a metal semiconductor field effect transistor (MESFET) and a high electron mobility transistor (HEMT) or the like.

As mentioned above, in the fourth to sixth exemplary embodiments, the examples are described in which the resonant circuit of the first exemplary embodiment is applied to a cascode distributed amplifier and an oscillator. However, the resonant circuits in the second or third exemplary embodiment or their varieties are also available for the resonant circuit to be applied to (but it is desirable to use the resonant circuit in the first exemplary embodiment for a distributed amplifier, as mentioned above). It is possible to apply these resonant circuits not only to the cascode distributed amplifier and the oscillator but also to other various high speed signal and high-frequency signal circuits.

Although the present invention has been described using exemplary embodiments above, the technical scope of the present invention is not limited to the range described in the above-mentioned exemplary embodiments. It is obvious to a person skilled in the art that various modifications or improvement can be added to the above-mentioned exemplary embodiments. It is clear from the description of the claims that an embodiment to which such modifications or improvement is added can be also included in the technical scope of the present invention.

It should be noted that execution sequence of each piece of processing of such as an operation, a procedure, a step, and a stage in the apparatus described in the claims, specification, and drawings can be realized in no particular order, unless “before something” and “in advance of something” and the like are clearly specified, or output of a previous process is used by the later process. Regarding an operation flow in the claims, specification, and drawings, even if it is described using words such as “first” and “next” for convenience, it does not mean that it is indispensable to carry out steps in this order.

The whole or part of the exemplary embodiments disclosed above can be described as, but not limited to, the following supplementary notes.

(Supplementary note 1) A resonant circuit, comprising: a stub; a first capacitance whose one to be connected to the stub and whose another end to be grounded; and a second capacitance whose one end to be connected to a connection between the stub and the first capacitance.

(Supplementary note 2) The resonant circuit according to Supplementary note 1, wherein the stub is an open stub having a length longer than a (¼+k) wavelength (k=0, 1, - - - ) in a resonance frequency by a 1/20 wavelength at most.

(Supplementary note 3) The resonant circuit according to Supplementary note 2, wherein the open stub and the first capacitance form a parallel resonance circuit at a frequency higher than a resonance frequency of the resonant circuit as a whole by 20% at most. (Supplementary note 4) The resonant circuit according to

Supplementary note 1, wherein the stub is a short stub having a length longer than a (½+k) wavelength (k=0, 1, - - - ) in a resonance frequency by a 1/20 wavelength at most.

(Supplementary note 5) The resonant circuit according to Supplementary note 4, wherein the short stub and the first capacitance form a parallel resonance circuit at a frequency higher than a resonance frequency of the resonant circuit as a whole by 20% at most.

(Supplementary note 6) A distributed amplifier, comprising: a transmission line connected to an output end and converting one of an output impedance and an input impedance into high impedance in a specific frequency band; and a resistance grounded circuit connected to the transmission line in parallel as viewed from one of an output terminal side and an input terminal side; wherein the resistance grounded circuit is configured in which a resistance having one of a load resistance value and a predetermined resistance value near a signal source resistance value is terminated by the resonant circuit according to any one of Supplementary notes 1, 2, 3, 4, and 5.

(Supplementary note 7) The distributed amplifier according to Supplementary note 6, wherein the plurality of resistance grounded circuits are comprised, each of which comprises the resonant circuit with a different resonance frequency.

(Supplementary note 8) An oscillator, comprising the resonant circuit according to any one of Supplementary notes 1, 2, 3, 4, and 5.

This application is based upon and claims the benefit of priority from Japanese Patent Application No. 2011-273121, filed on Dec. 14, 2011, the disclosure of which is incorporated herein in its entirety by reference.

### DESCRIPTION OF THE CODES

1, 1-1, 1-2 (λ/4+δ)-length open stub
2, 2-1, 2-2 grounded capacitance
3, 3-1, 3-2 capacitance
4 ((½+k)λ+δ)-length short stub
5 ((¼+k)λ+δ)-length open stub
22 input terminal
23 output terminal
24 collector power supply terminal
25 base power supply terminal
26 cascode power supply terminal
27-1, 2, - - - , n heterojunction Bipolar Transistor (HBT)
28-1, 2, - - - , n cascode HBT
29-1, 2, - - - , n transmission line
30-1, 2, - - - , n cascode grounded capacitance
31-1, 2, - - - , n cascode power-supply resistance
32-1, 2, - - - , n cascode pair
33-1, 2, - - - , n transmission line
34-1, 2, - - - , n input-side high impedance transmission line
35-1, 2, - - - , n input-side high impedance transmission line
36-1, 2, - - - , n transmission line
37-1, 2, - - - , n output-side high impedance transmission line
38-1, 2, - - - , n output-side high impedance transmission line
39 collector power-source resistance
40 base power-supply resistance
50 output end
51 reflection loss suppression circuit
52 transmission line
53, 53-1, 53-2 resistance grounding circuit
54, 54-1, 54-2 resistance
55, 55-1, 55-2 resonant circuit
61 output terminal
62 base power supply terminal
63 collector power supply terminal
64 HBT
65, 66, 67, 68 transmission line
69 base power supply circuit
70 collector power supply circuit
71, 72 quarter-wavelength transmission line
73, 74 grounded capacitance
75 output matching circuit
76 open stub
77 DC blocking capacitance
80 resonant circuit
81 (λ/2-δ)-length open stub
82 capacitance

What is claimed is:

1. A resonant circuit, comprising:
a stub;
a first capacitance having one end connected to the stub and having another end connected to ground; and
a second capacitance having one end connected to a connection between the stub and the first capacitance.

2. The resonant circuit according to claim 1,
wherein the stub is an open stub having a length longer than a (¼+k) wavelength (k=0, 1, - - - ) in a resonance frequency by a 1/20 wavelength at most.

3. The resonant circuit according to claim 2,
wherein the open stub and the first capacitance form a parallel resonance circuit at a frequency higher than a resonance frequency of the resonant circuit as a whole by 20% at most.

4. The resonant circuit according to claim 1,
wherein the stub is a short stub having a length longer than a (½+k) wavelength (k=0, 1, - - - ) in a resonance frequency by a 1/20 wavelength at most.

5. The resonant circuit according to claim 4,
wherein the short stub and the first capacitance form a parallel resonance circuit at a frequency higher than a resonance frequency of the resonant circuit as a whole by 20% at most.

6. A distributed amplifier, comprising:
a transmission line connected to an output end and converting one of an output impedance and an input impedance into high impedance in a specific frequency band; and
a resistance grounded circuit connected to the transmission line in parallel as viewed from one of an output terminal side and an input terminal side;
wherein the resistance grounded circuit is configured in which a resistance having one of a load resistance value and a predetermined resistance value near a signal source resistance value is terminated by a resonant circuit;
wherein the resonant circuit comprises a stub; a first capacitance having one end connected to the stub and having another end connected to ground; and a second capacitance having one end connected to a connection between the stub and the first capacitance.

7. The distributed amplifier according to claim 6,
wherein the plurality of resistance grounded circuits are comprised, each of which comprises the resonant circuit with a different resonance frequency.

8. An oscillator, comprising:
a resonant circuit;
the resonant circuit comprising a stub; a first capacitance having one end connected to the stub and having another end connected to ground; and a second capacitance having one end connected to a connection between the stub and the first capacitance.

9. The distributed amplifier according to claim 6,
wherein the stub is an open stub having a length longer than a (¼+k) wavelength (k=0, 1, - - - ) in a resonance frequency by a 1/20 wavelength at most.

10. The distributed amplifier according to claim 9,
wherein the open stub and the first capacitance form a parallel resonance circuit at a frequency higher than a resonance frequency of the resonant circuit as a whole by 20% at most.

11. The distributed amplifier according to claim 6,
wherein the stub is a short stub having a length longer than a (½+k) wavelength (k=0, 1, - - - ) in a resonance frequency by a 1/20 wavelength at most.

12. The distributed amplifier according to claim 11,
wherein the short stub and the first capacitance form a parallel resonance circuit at a frequency higher than a resonance frequency of the resonant circuit as a whole by 20% at most.

13. The oscillator according to claim 8,
wherein the stub is an open stub having a length longer than a (¼+k) wavelength (k=0, 1, - - - ) in a resonance frequency by a 1/20 wavelength at most.

14. The oscillator according to claim 13,
wherein the open stub and the first capacitance form a parallel resonance circuit at a frequency higher than a resonance frequency of the resonant circuit as a whole by 20% at most.

15. The oscillator according to claim 8,
wherein the stub is a short stub having a length longer than a (½+k) wavelength (k=0, 1, - - - ) in a resonance frequency by a 1/20 wavelength at most.

16. The oscillator according to claim 15,
wherein the short stub and the first capacitance form a parallel resonance circuit at a frequency higher than a resonance frequency of the resonant circuit as a whole by 20% at most.
